(19) United States
(12) Patent Application Publication
(10) Pub. No.: US 2025/0038021 A1
(43) Pub. Date: Jan. 30, 2025

(54) High Throughput Substrate Processing Cluster Tool With Factory Interface Centering

(71) Applicant: Applied Materials, Inc., Santa Clara, CA (US)

(72) Inventors: Upendra UMMETHALA, Santa Clara, CA (US); Tuan Anh NGUYEN, San Jose, CA (US); Kaushik ALAYAVALLI, Sunnyvale, CA (US)

(21) Appl. No.: 18/752,292

(22) Filed: Jun. 24, 2024

Related U.S. Application Data
(60) Provisional application No. 63/529,483, filed on Jul. 28, 2023.

(30) Foreign Application Priority Data
Oct. 28, 2023 (IN) 202341073512

(51) Int. Cl. H01L 21/67; H01L 21/677; H01L 21/687

(52) U.S. Cl. CPC H01L 21/67259; H01L 21/67173; H01L 21/67742; H01L 21/68707

(57) ABSTRACT

A cluster tool includes: a factory interface including a first robot with an end effector; a first processing mainframe coupled to the factory interface, including: a first processing chamber; a first load lock including a first opening facing the factory interface configured to receive the end effector of the first robot, the first load lock further including a first slit valve configured to selectively open and close the first opening; at least one first LCF sensor disposed between the factory interface and the first slit valve; and a swapper assembly disposed between the first load lock and the first processing chamber, wherein the swapper assembly includes a first swapper configured to swap substrates between the first processing chamber and the first load lock along a first trajectory.

### CROSS-REFERENCE TO RELATED APPLICATIONS

This application claims priority to and the benefit of U.S. Provisional Application No. 63/529,483 entitled “Swapper for a Cluster Tool” filed on Jul. 28, 2023. This application claims priority and the benefit under 35 U.S.C. § 119 (a) of Indian Provisional Patent Application No. 202341073512 filed Oct. 28, 2023. Each of the aforementioned applications are incorporated by reference herein.

### BACKGROUND

### Field

Embodiments of the present disclosure generally relate to the linear transport of substrates in a cluster tool.

### Description of the Related Art

Cluster tools are used in the manufacturing of semiconductor devices on substrates. Cluster tools have robotic mechanisms within a transfer chamber that are used to convey substrates between different chambers within the cluster tool. A substrate is placed in a load lock of the cluster tool and then may be transferred between multiple robotic mechanisms before being placed into a processing chamber that deposits or otherwise forms a layer or feature on the surface of the substrate.

The robotic mechanism used to transfer the substrate from the load lock to the processing chamber is operated to align the center of the substrate above the center of the substrate support within the processing chamber. This centering operation takes time to complete which lengthens the amount of time that the substrate is within the cluster tool. Additionally, conventional robotic mechanisms that transfer multiple substrates from the load lock to different processing chambers cannot center each substrate above a substrate support in each processing chamber simultaneously. Instead, the robot mechanism makes a series of movements to center and transfer each substrate to a respective processing chamber which takes time to complete, thereby lengthening the time that the substrates are within the cluster tool.

There is a need in the art for a method of rapidly, efficiently, and cost effectively transferring substrates from a load lock to a processing chamber.

### SUMMARY

In one embodiments, a cluster tool comprises: a factory interface including a first robot with an end effector; a first processing mainframe coupled to the factory interface, including: a first processing chamber; a first load lock including a first opening facing the factory interface configured to receive the end effector of the first robot, the first load lock further including a first slit valve configured to selectively open and close the first opening; at least one first LCF sensor disposed between the factory interface and the first slit valve; and a swapper assembly disposed between the first load lock and the first processing chamber, wherein the swapper assembly includes a first swapper configured to swap substrates between the first processing chamber and the first load lock along a first trajectory.

In one embodiment, a method of operating a cluster tool comprises: engaging a first substrate with a first robot of a factory interface of the cluster tool; moving the first substrate engaged with the first robot along a first trajectory to place the first substrate at a load lock transfer position within a first load lock of the cluster tool; and detecting for a deviation from the first trajectory using a first LCF sensor disposed between the factory interface and a first slit valve of the first load lock.

In one embodiment, a method of operating a cluster tool comprises: engaging a first substrate with a first robot of a factory interface of the cluster tool; obtaining first positional data of the first substrate engaged with the first robot using a first LCF sensor disposed between the factory interface and an opened first slit valve of a first load lock of the cluster tool; and adjusting a position of the first robot based on the obtained first positional data to place the first substrate at a load lock transfer position within the first load lock.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A illustrates an isometric view of an exemplary cluster tool used to fabricate substrates, according to embodiments described herein.

FIG. 1B illustrates an isometric view of an exemplary cluster tool used to fabricate substrates in a stacked configuration, according to embodiments described herein.

FIG. 2A illustrates a schematic plan view of an exemplary cluster tool with the swappers in an extended position, according to embodiments described herein.

FIG. 2B is a schematic partial cross-sectional view of a swapper assembly of the cluster tool shown in FIG. 2A, according to embodiments described herein.

FIG. 2C illustrates a schematic plan view of the exemplary cluster tool shown in FIG. 2A with the swappers in a retracted position, according to embodiments described herein.

FIG. 3A is a schematic partial cross-sectional view of a swapper assembly, according to embodiments described herein.

FIG. 3B is a partial exploded view of a swapper, according to embodiments herein.

FIG. 4 illustrates a flow chart of an exemplary method of operating a cluster tool, according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally provides an apparatus and method for processing substrates using a multi-chamber processing system (e.g., a cluster tool) adapted to process substrates. A cluster tool is a system comprising multiple chambers which perform various functions in the electronic device fabrication process. The cluster tool includes at least two swapping mechanisms operated by the same or different motor assembly to transfer substrates between two chambers within the cluster tool.

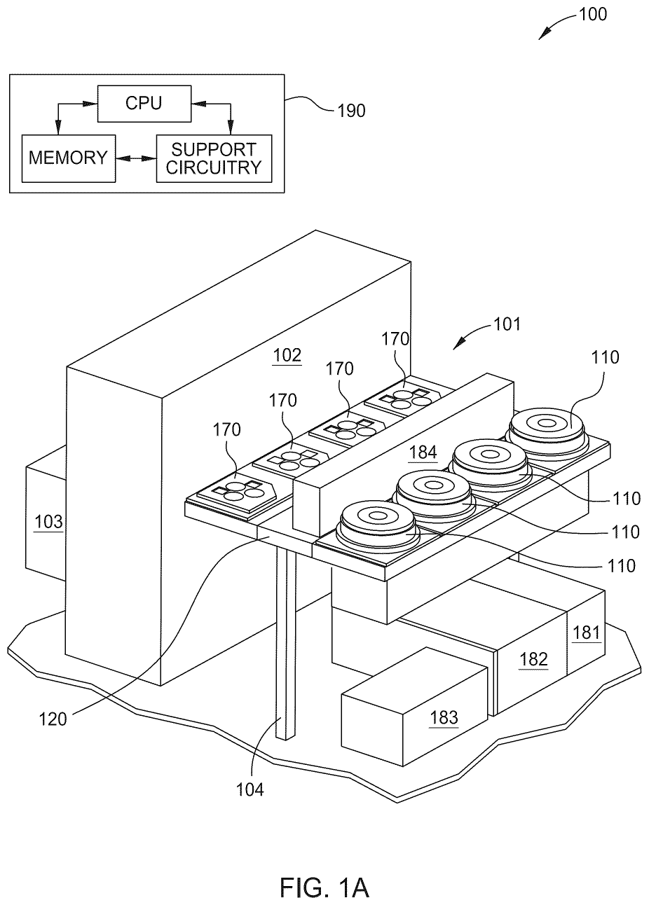

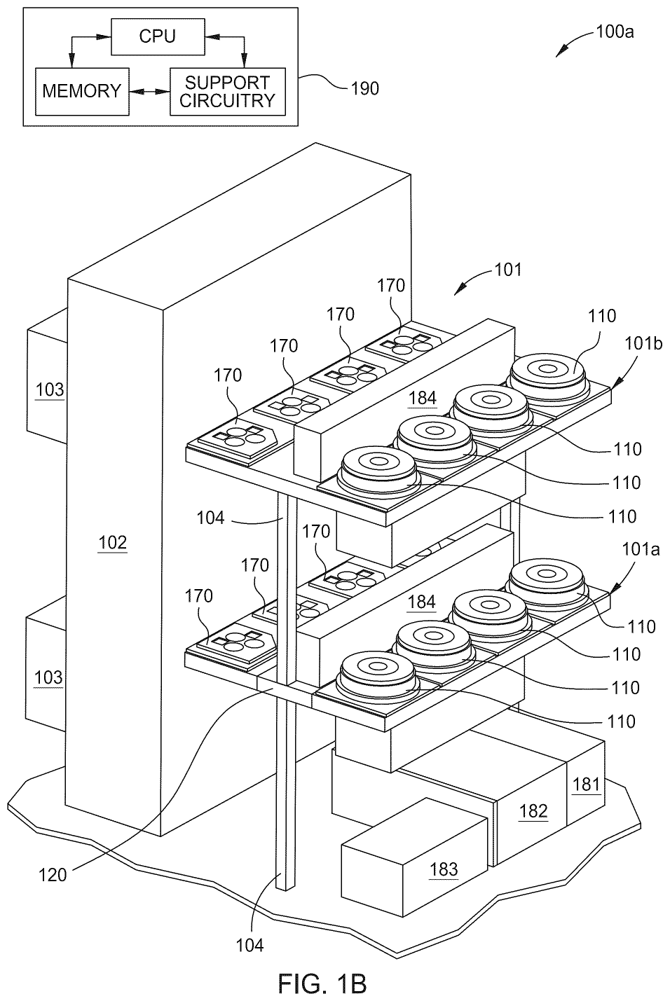

FIG. 1A is an isometric view of one embodiment of a cluster tool 100 used to fabricate substrates. The cluster tool 100 includes a factory interface 102 and at least one processing mainframe 101.

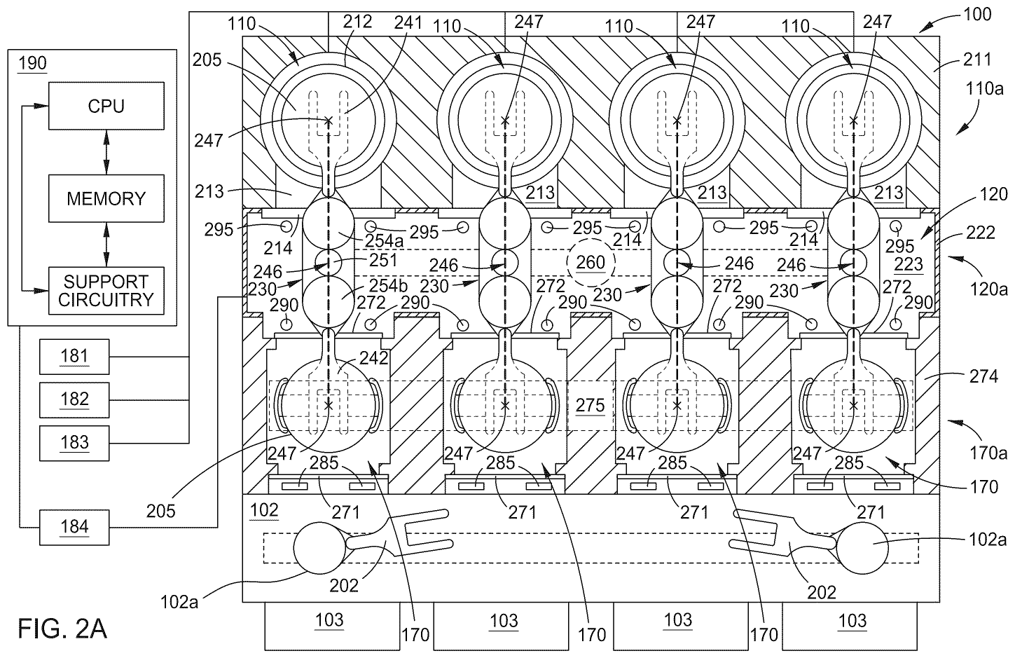

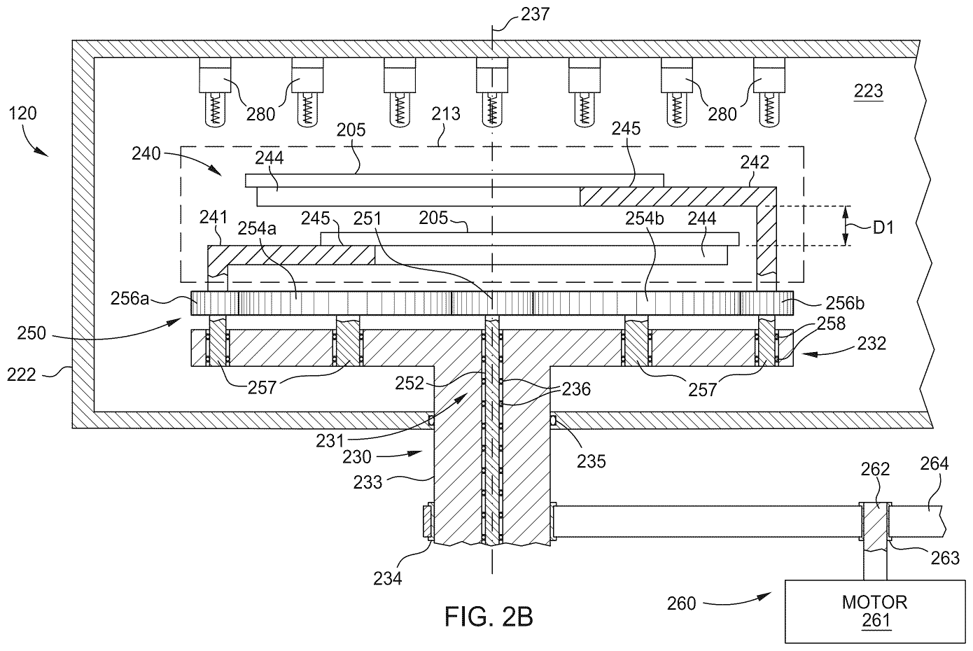

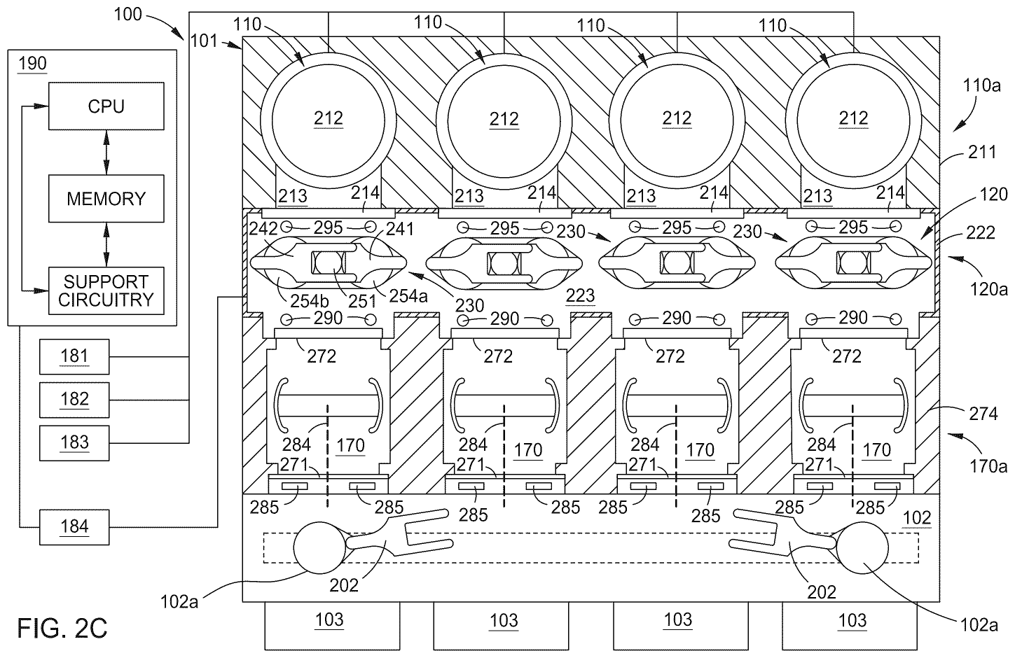

The processing mainframe 101 includes, at least two substrate processing chambers 110, a substrate swapper assembly 120, at least two load locks 170, and a controller 190. While not intended to be limiting as to the scope of the disclosure provided herein, the disclosure provided herein primarily describes an embodiment of the disclosure that includes a processing mainframe 101 that includes at least four substrate processing chambers 110, a substrate swapper assembly 120, at least four load locks 170, and a controller 190. The load locks 170 and processing chambers 110 can be grouped in pairs, with each grouping having one load lock 170 opposing a corresponding processing chamber 110. The substrate swapper assembly 120 is located between the processing chambers 110 and the load locks 170. The substrate swapper assembly 120 includes a swapper (such as swapper 230 in FIG. 2A) for each pair of the processing chambers 110 and load locks 170, and each swapper is used to swap (e.g., move) substrates (see substrate 205 in FIG. 2A) between the corresponding processing chamber 110 and load lock 170. The processing mainframe 101 may be supported in a position relative to the factory interface 102 by one or more supports 104, which may be a frame, used to support the weight of the processing mainframe 101.

As shown in FIG. 1A, the processing mainframe 101 includes four processing chamber 110 and load lock 170 pairs. In some embodiments, the processing mainframe 101 may have only one processing chamber 110 and load lock 170 pair. In some embodiments, the processing mainframe 101 may have two or three processing chamber 110 and load lock 170 pairs. In some embodiments, the processing mainframe 101 may have more than four processing chamber 110 and load lock 170 pairs, as illustrated in FIG. 1A. In some embodiments, the processing mainframe 101 may have more than five processing chamber 110 and load lock 170 pairs or six processing chamber 110 and load lock 170 pairs.

The processing chambers 110 include a substrate support (e.g., pedestal, platen) and a processing kit and source assembly configured to process the substrate within the processing chamber 110. The processing chambers 110 may perform any number of processes such as preclean, chemical vapor deposition (CVD), plasma enhanced chemical vapor deposition (PECVD), physical vapor deposition (PVD), atomic layer deposition (ALD), decoupled plasma nitridation (DPN), rapid thermal processing (RTP), ashing, annealing, and etching, or any processing chamber utilized in electronic device fabrication. In one embodiment, the processing sequence is adapted to form a high-K capacitor structure, where processing chambers 110 may be a DPN chamber, a CVD chamber capable of depositing poly-silicon, and/or a MCVD chamber capable of depositing titanium, tungsten, tantalum, platinum, or ruthenium.

In some embodiments, the processing chamber 110 includes one or more lift pins. The lift pins are coupled to the substrate support. The substrate is transferred from the swapper to the lift pins. The lift pins then transfer the substrate to the substrate support. In some embodiments, the substrate support is raised to sealingly engage with the process kit assembly to form an isolated processing region around the substrate where the substrate is subjected to a process, such as a PVD process. Once the process is complete, the substrate support is lowered and the substrate is disengaged from the substrate support by the lift pins. The substrate is then transferred from the lift pins and onto the swapper, such as by placing a support surface of the swapper underneath the substrate and retracing the lift pins.

The factory interface 102 may be coupled to one or more front opening unified pods (FOUPs) 103. FOUPs 103 may each be a container having a stationary cassette therein for holding multiple substrates. FOUPs 103 may each have a front opening interface configured to be used with factory interface 102. Factory interface 102 may have a buffer chamber (not shown) and one or more robots 102a (as shown in FIG. 2A) configured to transfer substrates via linear, rotational, and/or vertical movement between FOUPs 103 and the load locks 170. The factory interface 102 may include a set of FOUPs 103 and corresponding one or more robots 102a for each processing mainframe 101. The robots 102a are used to transfer substrates between the FOUPs 103 load lock 170. The robots 102a place the substrate at a load lock transfer position within the load lock 170. Lift pins within the load lock 170 are raised to disengage the substrate from the end effector (see end effector 202 in FIG. 2A) of the robot 102a, thereby transferring the substrate from the robot 102a to the load lock 170. As will be explained in more detail below, the load lock transfer position is selected to center the substrate within the cluster tool 100. In other words, the robots 102a place the substrate at a location within the load lock 170 such that the swapper 230 can move the substrate into the processing chamber 110 without making a location center finding adjustment to increase the throughput of the cluster tool 100.

Each swapper 230 (FIG. 2A) in the swapper assembly 120 swaps the substrate in each load lock 170 and the processing chamber 110 pair along a trajectory. Thus, each substrate is not transferred between multiple robotic arms to transfer the substrate from the load lock 170 to the processing chamber 110, which increases the throughput of the cluster tool 100 as compared to conventional cluster tools that require multiple transfer steps to move a substrate into a processing chamber.

Additionally, the swapper assembly 120 may have one motor assembly 260 (FIG. 2A) that includes a single motor that is used to operate all the swappers 230 simultaneously. Thus, one motor assembly may be used to cause the swapping of the substrates in all the pairs of processing chambers 110 and load locks 170 of each processing mainframe 101. In some embodiments, each swapper 230 of the swapper assembly 120 is operated by a different motor assembly, and is thus operated by one or more different motors. Thus, the swapper assembly 120 may have four motors that correspond with the four swappers. In some embodiments, two or more swappers of the swapper assembly share a motor assembly, thus sharing one motor, while the remaining swappers are operated by one or more different motor assemblies. For example, the swapper assembly 120 may have four swappers, and two swappers of the swapper assembly 120 may be operated by a first motor assembly with a first motor while the other two swappers are operated by a different motor assembly with a second motor.

In some embodiments, the processing chambers 110 are part of a monolithic structure, such as sharing a common housing. In some embodiments, the swapper assembly 120 and the load locks 170 may each be part of a separate monolithic structure. Thus, in this case, the processing mainframe 101 may be formed by connecting a monolithic structure including the processing chambers 110 to one side of the monolithic structure of the swapper assembly 120 and then also connecting a monolithic structure including the load locks 170 to the other side of the monolithic structure including of the swapper assembly 120. Assembling the cluster tool 100 from monolithic structures, each including multiple components, such as processing chambers 110, load locks 170, or swapper assembly 120, decreases manufacturing and assembly costs and reduces the number of leak points. In some other embodiments, the processing chambers 110, the swapper assembly 120 and the load locks 170 may each be part of a single monolithic structure that is used to support and provide a positional reference for the mounting and aligning of the various components to each other and to the monolithic structure.

The cluster tool 100 may also include a pumping system 181, a gas panel 182, a power supply 183, and an electronics module 184. The pumping system 181, gas panel 182, and power supply 183 are shown disposed underneath of the processing mainframe 101. The pumping system 181 is used to create and/or maintain a pressure within each processing chamber 110. For example, the pumping system 181 may be a vacuum pump or a plurality of vacuum pumps used to evacuate the processing chambers 110. The gas panel 182 may include one or more gases used to process a substrate in the processing chamber. The power supply 183 may be a power source, such as an AC power source or a DC power source, to operate electrical equipment of the cluster tool 100, such as operating equipment in the processing chamber 110, such as the source assembly. The power supply 183 may also include an optional RF power supply for the processing chambers 110, such as supplying RF power to a shower head or an electrostatic chuck of the processing chamber. The electronics module 184 may include electronics used to monitor and control the cluster tool 100. The electronics module 184 may be in communication with the controller 190.

In some embodiments, the pumping system 181 is also used to create and maintain a pressure within the load locks 170, such as being used to evacuate each load lock 170. The pumping system 181 may also be used to create and maintain a pressure within the swapper assembly 120, such as being used to evacuate the swapper assembly 120. In some embodiments, the cluster tool 100 includes a separate pumping system 181 for each of the processing chambers 110, the swapper assembly 120, and the load locks 170.

In some embodiments, there is a pressure gradient in the processing mainframe 101. For example, the magnitude of the vacuum within the processing mainframe 101 may increase from the load lock 170 (highest pressure) to the interior of the processing chambers 110 (lowest pressure). The pumping system 181 may be used to maintain the pressure gradient.

In some embodiments, the pumping system 181 may include one or more abatement modules to remove or break down chemicals or materials in the fore line to increase vacuum (e.g., exhaust) pump longevity.

FIG. 1B illustrates an isometric view of one embodiment of a cluster tool 100a used to fabricate substrates. Cluster tool 100a is similar to cluster tool 100 shown in FIG. 1, except that it includes multiple processing mainframes 101 in a stacked configuration, such as first processing mainframe 101a and a second processing mainframe 101b. The second processing mainframe 101b is supported above the first processing mainframe 101a by one or more supports 104.

As shown in FIG. 1B, the factory interface 102 has a set of FOUPs for both the first processing mainframe 101a and the second processing mainframe 101b. In some embodiments, the cluster tool 100 has a plurality of processing mainframes 101 while the factory interface 102 has one set of FOUPs and a corresponding set of robots 102a to transfer the substrates to and from the FOUPs to the load locks 170 of the plurality of processing mainframes 101.

The controller 190 may include a programmable central processing unit (CPU) which is operable with a memory (e.g., non-transitory computer readable medium and/or non-volatile memory) and support circuits. The support circuits are coupled to the CPU and includes cache, clock circuits, input/output subsystems, power supplies, and the like, and combinations thereof coupled to the various components of the cluster tool 100, to facilitate control of the cluster tool 100. For example, in one or more embodiments the CPU is one of any form of general purpose computer processor used in an industrial setting, such as a programmable logic controller (PLC), for controlling various polishing system components and sub-processors. The memory, coupled to the CPU, is non-transitory and is one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates the operation of the cluster tool 100. The instructions in the memory are in the form of a program product such as a program that implements the methods of the present disclosure (e.g., middleware application, equipment software application, etc.). The program code may conform to any one of a number of different programming languages. In one or more embodiments, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

The various methods (such as operations 401-412) and operations disclosed herein may generally be implemented under the control of the CPU of the controller 190 by the CPU executing computer instruction code stored in the memory (or in memory of a particular processing chamber) as, e.g., a software routine. When the computer instruction code is executed by the CPU, the CPU controls the components of the cluster tool 100 to conduct operations in accordance with the various methods and operations described herein. In one or more embodiments, the memory (a non-transitory computer readable medium) includes instructions stored therein that, when executed, cause the methods (such as the operations 401-412) and operations (such as the operations 401-412) described herein to be conducted. The operations described herein can be stored in the memory in the form of computer readable logic.

FIG. 2A illustrates a schematic plan view of an exemplary embodiment of cluster tool 100 shown in FIG. 1A. As shown, the cluster tool has four load locks 170, four processing chambers 110, and four swappers 230 disposed in the swapper assembly 120 configured to swap substrates 205 between each pair of load locks 170 and processing chambers 110.

Each processing chamber 110 may include a substrate support 212. The substrate support 212 may include one or more lift pins to lift and lower the substrate 205 relative to the substrate support 212, such as using the lift pins to transfer the substrate 205 to or from the swapper 230. In some embodiments, a slit valve 214 is located between the processing chamber 110 and the swapper assembly 120. When the slit valve 214 is in an open position, the swapper 230 is allowed to enter the processing chamber 110 through a tunnel 213 (e.g., opening) that leads to the interior of the processing chamber 110. When the slit valve 214 is in the closed position, the tunnel 213 is covered and the processing chamber 110 is isolated from the swapper assembly 120. In some embodiments, the slit valve 214 is omitted from the system.

In some embodiments, each processing chamber 110 may be contained in the same monolithic housing 211. Thus, processing chambers 110 are part of a monolithic processing chamber structure 110a that can be attached to the swapper assembly 120 on the side opposite from the load locks 170. In some embodiments, the processing chambers 110 do not all share the same housing. For example, each processing chamber 110 may have separate housing 211. In some embodiments, starting from the left-hand side of FIG. 2A, the two left-most processing chambers 110 may share a housing 211 and the two processing chambers 110 may share a separate housing 211.

Each load lock 170 may have a first slit valve 271 and a second slit valve 272. When the first slit valve 271 is open, a substrate 205 can be transferred from the factory interface 102 and to support members, such as lift pins, positioned in the load lock 170. When the first slit valve 271 is closed, the interior of the load lock 170 is isolated from the factory interface 102. Thus, the load locks 170 provide a vacuum interface between the factory interface 102 (e.g., front-end environment) and the remainder of the cluster tool 100. When the second slit valve 272 is open, the swapper 230 is allowed to enter the load lock 170 where the substrate 205 is then transferred to the swapper 230. When the second slit valve 272 is closed, the interior of the load lock 170 is isolated from the swapper assembly 120 and the processing chambers 110. In some embodiments, the first slit valves 271 may be disposed at an angle relative to the factory interface to facilitate allowing a robot of the factory interface 102 to enter the load lock 170 to receive the substrate 205 from the swapper 230.

The four load locks 170 are shown contained in the same housing 274. Thus, the load locks 170 are part of a monolithic load lock structure 170a that can be attached to the factory interface 102 and also attached to the swapper assembly 120 on the side opposite of the processing chambers 110. In some embodiments, the load locks 170 do not all share the same housing. For example, each load lock 170 may have separate housing. In some embodiments, starting from the left-hand side of FIG. 2A, the two left-most load locks 170 may share a housing 274 and the two right-most load locks 170 may share a separate housing.

In some embodiments, the four load locks 170 share a lift 275, as shown in FIG. 2A, disposed underneath the housing 274. The lift 275 is configured to raise and lower the lift pins of the load locks 170 in unison. These lift pins are engageable with the substrate 205 to facilitate handing the substrate 205 off to the robotic arm of the factory interface 102 or the swapper 230. Thus, the lift 275 can control the simultaneous transfer of a substrate 205 onto or from either the robot 102a of the factory interface 102 or the swapper 230.

The lift 275 may be a plate that extends underneath the chamber of the load locks 170 connected to the lift pins. An actuator, such as a hydraulic, pneumatic, or electric actuator, may be used to move the plate axially to change the position of the lift pins. In some embodiments, each load lock 170 has a separate lift 275.

FIGS. 2A-2C illustrate an exemplary embodiment of the swapper assembly 120, with FIG. 2B showing a schematic partial side cross-sectional view of the swapper assembly 120 (i.e., far right side of FIG. 2A). The swapper assembly 120 additionally includes a housing 222 and a motor assembly 260. The housing 222 defines an internal swapper chamber 223. The swappers 230 are partially disposed in the swapper chamber 223, and the substrates pass through the swapper chamber 223 between the load locks 170 and the processing chamber 110. Each swapper 230 may be operated by the same motor assembly 260 which is located outside of the swapper chamber 223, such as being disposed underneath the swapper chamber 223 as shown in FIG. 2A.

In some embodiments, each swapper 230 is in the same swapper chamber 223. In some embodiments, a wall of the housing 222 bifurcates the swapper chamber 223 such that each swapper 230 is isolated from the other or isolates a pair of swappers 230 from another pair of swappers 230.

In some embodiments, all four swappers 230 are disposed in the same housing 222. Thus, the swapper assembly 120 may be part of a monolithic swapper assembly structure 120a that is attachable to the monolithic load lock structure 170a.

FIGS. 2A-2C illustrate an exemplary embodiment of the swappers 230. Only one swapper 230 (left-most swapper 230 in FIG. 2A) is fully labeled for clarity. However, this swapper 230 is representative of all the other swappers 230. Each swapper 230 includes a body 231 that includes an upper portion 232 and a shaft 233 that extends downward from the upper portion 232. The shaft 233 includes a body pulley 234. A seal element 235 may be disposed around the shaft 233 to seal the swapper chamber 223 from the outside environment while facilitating the rotation of the body 231 relative to the housing 222. The upper portion 232 supports an arm assembly 240 and a gear assembly 250 of the swapper 230. The arm assembly 240 includes a first arm 241 (e.g., left arm) and a second arm 242 (e.g., right arm) that are rotated by a gear assembly 250. The arms 241, 242 are moveable to extended positions where each arm 241, 242 is located within either the load lock 170 or the processing chamber 110 to convey a substrate 205 disposed on the arm 241, 242. FIG. 2A shows the first arm 241 in an extended position, with the first arm 241 positioned within the processing chamber 110 above the substrate support 212 while the second arm 242 is shown in an extended positioned within the load lock 170. The arms 241, 242 are moved to swap positions, such that the first arm 241 is moved to an extended position within the load lock 170 while the second arm 242 is moved to an extend position within the processing chamber 110. The arms 241, 242 may also be moved to a retracted position (FIGS. 2B and 2C) where the arms 241, 242 overlap one another.

The arms 241, 242 each include a support 244 with a support surface 245. As shown in FIG. 2A, the support 244 may have a fork shape. One prong of the fork may be shorter than the other prong, or both prongs may have the same length. The substrate 205 is placed into engagement with a support surface 245 of the support 244. The support 244 carries the substrate 205 disposed thereon as the swapper 230 moves the substrate 205 between the load lock 170 and the processing chamber 110. As shown in FIG. 2B, the support 244 of the first arm 241 and second arm 242 are located at different heights such that one arm can pass underneath the other arm without the substrate 205 on the lower arm contacting the upper arm. As shown, the first arm 241 is located at a height above the upper portion 232 that is lower than the second arm 242. A distance, shown as D1, is present between the support surface 245 of the support 244 of the first arm 241 and the underside of the second arm 242. This distance D1 is sized to allow the substrate 205 to pass underneath the second arm 242 without contacting the second arm 242. Additionally, the opening between the load lock 170 and the swapper assembly 120 that can be covered by the second slit valve 272 is sized to allow the arms 241, 242 to enter and exit the load lock 170 without the arms 241, 242 or the substrate 205 disposed thereon contacting a surface of the opening. The tunnel 213 (shown as dashed opening) between the processing chamber 110 and the swapper assembly 120 that can be covered by the slit valve 214 is also sized to allow the arms 241, 242 to enter and exit the processing chamber 110 without the arms 241, 242 or the substrate 205 disposed thereon contacting a surface of the tunnel 213.

FIG. 2A shows a substrate 205 placed on the support 244 of each arm 241, 242. A portion of each arm 241, 242 is shown in dashed to illustrate that the substrate 205 is supported on the corresponding arm 241, 242. An illustrative trajectory point 247 is shown for each support 244. The trajectory point 247 will follow the trajectory 246 as the motor assembly 260 operates the swapper 230 to move the arms 241, 242. The trajectory point 247 is shown being between the two forks of the support 244, but the trajectory point 247 may be located at a point on the support surface 245 depending on the shape of the support 244. In some embodiments, the trajectory 246 (shown as a dashed line in FIG. 2A) is a substantially linear path that extends from the center point of the substrate support 212, over the central axis 237 of the swapper 230, to a center point of the load lock 170. In other words, this illustrative point 247 moves linearly as the first arm 241 and second arm 242 swap positions. The substrate 205 disposed on the support 244 of each arm 241, 242 similarly moves in a linear fashion along the trajectory 246. Thus, the swapper 230 is used to move the substrates in a linear trajectory between the load lock 170 and processing chamber 110, and vice versa. The arms 241, 242 move the substrate 205 disposed thereon along parallel linear trajectories that are separated by a distance since each arm is located at a different height. And, as shown in FIG. 2A, each pair of processing chambers 110 and load locks 170 are positioned opposing each other across the swapper assembly 120 such that the linear trajectory of the substrates 205 moved by one swapper 230 is parallel to the linear trajectory of the substrates 205 moved by the other swapper 230.

Referring back to FIG. 2B, the gear assembly 250 includes a central gear 251, a first idler gear 254a, a second idler gear 254b, and a first arm gear 256a, and a second arm gear 256b. The first arm 241 is attached to the first arm gear 256a and the second arm 242 is attached to the second arm gear 256b. The central gear 251 is shown as stationary. For example, the central gear 251 may be fixed on a shaft 252, shown in FIG. 2B, that extends through the upper portion 232 and the shaft 233 of the body 231. The body 231 may include one or more bearing elements 236 to facilitate the rotation of the body 231 relative to the stationary shaft 252. The bearing elements 236 may be a ball bearing, a spherical roller bearing, or other bearing element suitable to facilitate rotation between the body 231 and the shaft 252. The idler gears 254a,b and arm gears 256a,b may be mounted on a shaft 257 that is coupled to the upper portion 232. For example, a plurality of bearing elements 258 (similar to bearing elements 236) are embedded in the upper portion 232 to facilitate the rotation of the shaft 257, and thus the rotation of the gear attached to the corresponding shaft 257, relative to the body 231. In some embodiments, the shaft 257 is fixed to the body 231 and a plurality of bearing elements 258 are disposed around the shaft 257 between the corresponding gear and the shaft 257.

FIG. 2B shows the motor assembly 260 connected with one swapper 230, which is representative of the connection of the motor assembly 260 with the other swappers 230 shown in FIG. 2A. The motor assembly 260 includes a single motor 261 that rotates an output shaft 262. In other words, the motor assembly 260 may include one, and only one, motor 261 to operate multiple swappers 230 instead of using different motor to operate each swapper 230 in some embodiments. The output shaft 262 includes a motor pulley 263. A belt 264 is connected to the motor pulley 263 and loops around the body pulley 234 of each swapper 230. The belt 264 transfers rotational power from the motor pulley 263 to each body pulley 234, which causes the body 231 to rotate about a central axis 237 of the swapper 230. In some embodiments, the motor 261 may be an electrical, hydraulic, or pneumatic motor. In some embodiments, the body pulleys 234 and motor pulley 263 may each have a groove that corresponds with the shape of the belt 264. In some embodiments, the body pulleys 234 and motor pulley 263 may each have teeth that interface with the teeth of the belt 264. In some embodiments, the belt 264 may be substituted for a chain, with the motor pulley 263 and body pulleys 234 being substituted for a sprocket that interfaces with the chain.

In some embodiments, each swapper 230 is operated by a separate motor assembly 260 with a separate motor 261. In some embodiments, pairs of swappers 230 are operated by separate motor assemblies 260. For example, starting from the left-hand side of FIG. 2A, the two left-most swappers 230 may be operated by a first motor assembly 260 while two right-most swappers 230 may be operated by a second motor assembly 260.

As the body 231 of the swapper 230 rotates, the idler gears 254a,b rotate (e.g., orbit) around the stationary central gear 251. The central gear 251 has teeth that interface with corresponding teeth on the idler gears 254a,b. The engagement of the central gear 251 with the orbiting idler gears 254a,b causes the idler gears 254a,b to rotate relative to the body 231 in a first direction. These idler gears 254a,b also have teeth that interface with the teeth of the arm gears 256a,b to cause the arm gears 256a,b to rotate relative to the body 231 in a second direction. The rotation of the arm gears 256a,b causes the corresponding arm 241, 242 attached thereto to rotate relative to the body 231.

The gear ratio of the gear assembly 250 is configured to achieve a desired shape and resolution of the trajectory (e.g., path) in which the substrate 205 is transferred between the load lock 170 and processing chamber 110. In some embodiments, the gear ratio for the central gear 251 to the arm gears 256a,b is a 1:2 ratio to achieve the linear movement of the substrate 205 by moving the point 247 of the support 244 along the linear trajectory 246 as shown in FIG. 2A. In other words, one full orbit of an idler gear 254a,b around the central gear 251 causes the corresponding arm gear 256a,b to rotate twice.

The controller 190 can be in communication with the motor assembly 260 to control the position of the arms 241, 242 of the swappers 230. Operating the all the swappers 230 with the same motor assembly 260 allows every swapper 230 to be moved in a synchronous fashion. In some embodiments, the swappers 230 are arranged as shown in FIG. 2A where the arms 241, 242 of one swapper 230 move synchronously with the corresponding arm 241, 242 of the other swapper 230. In some embodiments, the swappers 230 are offset to one another. For example, one swapper 230 may have both arms 241, 242 in an extended position while the arms 241, 242 of the other swapper 230 are positioned in the retracted position.

The swapper 230 is repeatedly operated to move the arms 241, 242 to the extended position within the load lock 170 and to the extended position within the processing chamber 110. The movement of the first arm 241 and the second arm 242 is consistent over each swapping cycle. The center point 247 of each arm 241, 242 is consistently placed in a position within the load lock 170 when each arm 241, 242 is moved to the extended position within the load lock 170. Similarly, the center point 247 of each arm 241, 242 is consistently placed in a position within the processing chamber 110 above the substrate support 212 when each arm 241, 242 is moved to the extended position within the processing chamber 110. The position of the center point 247 within the load lock 170 or processing chamber 110 when the arms 241, 242 are in the extended position may vary negligibly between each cycle of swapping the substrates 205. For example, the position of the center point 247 when the arms 241, 242 are in the extended position may vary about 100 microns between each cycle.

The robot 102a places the substrate 205 in the load lock transfer position within the load lock 170. The center of the substrate 205 within the load lock 170 is known when the substrate 205 is in the load lock transfer position. The lift 275 is then used to transfer the substrate 205 from the end effector 202 of the robot 102a onto the lift pins of the load lock 170. An arm of the swapper 230, such as the first arm 241, is moved to the extended position within the load lock 170 underneath the substrate 205. The lift 275 then lowers the substrate 205 to transfer the substrate 205 from the lift pins to the first arm 241. The center of the substrate 205 is placed in a known position relative to the center 247 of the first arm 241 due to the consistency of the placement of the center point 247 within the load lock 170. The first arm 241 is then moved to the extended position within the processing chamber 110, which places the center of the substrate 205 into alignment or an acceptable alignment with the substrate support 212 due to the consistency of the placement of the center point 247 within the processing chamber 110. Therefore, the load lock transfer position is selected such that the center of the substrate 205 is within an acceptable alignment with the center of the substrate support 212 when the substrate 205 is transferred to the substrate support 212. For example, the load lock transfer position may be selected based on an offset in the center of the load lock 170 and the substrate support 212 of a processing chamber 110.

In other words, the robot 102a may be used to place the substrate 205 in a load lock transfer position that facilitates the alignment of the substrate 205 with the center of the substrate support 212. This allows the swapper 230 to be actuated to move the arms 241, 242 to place an unprocessed substrate 205 disposed thereon within an acceptable alignment of the substrate support 205 without one or more fine tuning motions to achieve the alignment between the substrate 205 and substrate support 212 based on feedback from location center finding sensors (“LCF”) within the processing chamber 110. As a result, using the robot 102a to align the substrate 205 instead of the swapper 230 decreases the overall process time of the substrate 205 within the cluster tool 100 which increases throughput.

As shown in FIG. 2A, the load lock assembly 170a includes a plurality of first LCF sensors 285 in communication with the controller 190. Each load lock 170 includes one or more of the plurality of first LCF sensors 285. The first LCF sensors 285 of each load lock 170 are positioned between the factory interface 102 and the first slit valve 271. For example, the first LCF sensors 285 may be disposed in the wall of the load lock 170 defining the opening facing the factory interface 102 that is selectively opened and closed by the first slit valve 271. In some embodiments, the first LCF sensors 285 are exposed to the atmosphere. These first LCF sensors 285 may be optical sensors used to detect the edges of the substrate 205.

In some embodiments, the first LCF sensors 285 are actively used to control the robots 102a to place the substrate 205 in the load lock transfer position. For example, the robot 102a may be a multi-axis robot, in that the robot 102a may be used to adjust position of the substrate along multiple axes. The swappers 230, on the other hand, may be single axis robots, in that the swappers 230 simply swap position of the arms 241, 242 (and move the arms to a retracted position) along the trajectory but lack the ability to adjust the center of the substrate along more than one axis. The one or more LCF sensors 285 of a load lock 170 may send positional data to the controller 190 about the position of the substrate 205 as the robot 102a moves the substrate 205 into the load lock 170. The controller 190 may use this data to adjust the position of the end effector 202 in one or more axes one or more times to place the substrate 205 in a desired load lock transfer position.

Actively controlling the robots 102a based on the feedback of the first LCF sensors 285 takes time and thus decreases throughput. In some embodiments, the controller 190 passively uses the positional data obtained by the plurality of first LCF sensors 285 to monitor the placement of the substrates 205 into the load lock 170 rather than actively controlling the robots 102a to place a substrate 205 within the load lock 170 based on the positional data. The robots 102a are calibrated and programmed to repeatedly pick up a substrate 205 from a FOUP 103 and place the substrate at the desired load lock transfer position. Thus, the substrate 205 will follow an expected trajectory (e.g., expected travel path) as the robot 102a moves the substrate 205 from the FOUP 103 to the load lock transfer position. FIG. 2C shows a portion of an expected trajectory 284, shown as dashed line, of the substrate 205 as the robot 102a moves the substrate 205 to the load lock transfer position. As shown, the portion of the expected trajectory 284 passes through the opening of the load lock 170 facing the factory interface 102. While the portion of the expected trajectory 284 is shown as a linear trajectory, the expected trajectory 284 may be non-linear, such as arcuate. The one or more first LCF sensors 285 monitor the position of the substrate 205 as the substrate 205 moves along the expected trajectory 284 that passes through the area sensed by the one or more first LCF sensors 285. The one or more first LCF sensors 285 of each load lock 170 monitor the movement of the substrate 205 for deviations from the expected trajectory. In other words, the feedback from the first LCF sensors 285 is not used to actively control and adjust the position of the robot 102a. Throughput through the cluster tool 100 is therefore increased since the time associated with actively adjusting the position of the robot 102a to position the substrate 205 is omitted.

Wear and tear of the robots 102a over repeated cycles of transferring substrates 205 to and from the load lock 170 may result in the substrate 205 deviating from the expected trajectory. A deviation from the expected trajectory can result in the substrate 205 being placed in an unsatisfactory load lock transfer position, such as a position that will cause the substrate 205 to be significantly misaligned when placed on the substrate support 212. The controller 190 may generate an alert on a user interface and/or stop operation of the cluster tool 100 when a deviation is detected. The robot 102a may then be recalibrated and/or repaired to correct the deviation.

The swapper assembly 120 may include a plurality of additional LCF sensors, such as a plurality of second LCF sensors 290 and a plurality of third LCF sensors 295, to monitor the movement of the swappers 230. The plurality of second LCF sensors 290 and third LCF sensors 295 may be disposed in the swapper chamber 223 and in communication with the controller 190. One or more of the plurality of the second LCF sensors 290 may be disposed adjacent to each second slit valve 272 to monitor one of the swappers 230. Similarly, one or more of the plurality of third LCF sensors 295 may be disposed adjacent to each slit valve 214 to monitor one of the swappers 230. The swappers 230 move the substrates 205 along the trajectory 246 from the load lock 170 to the processing chamber 110. The position of the center of the substrate 205 relative to the center point 247 of the respective arm 241, 242 is known based on the selected load lock transfer position. Thus, the controller 190 is able to determine where the substrate 205 should be as the substrate 205 moves along the trajectory 246.

The second LCF sensors 290 and third LCF sensors 295 monitor the travel of the substrates 205 along the trajectory 246 through the swapper chamber 223 as the arms 241, 242 swap positions. The second LCF sensors 290 and third LCF sensors 295 monitor for deviations in the travel of the substrates 205 along the trajectory 246, which are indicative of a malfunction of the swapper 230 or indicative of an arm 241, 242 moving in an undesired fashion. The controller 190 may generate an alert on a user interface and/or stop operation of the cluster tool 100 when a deviation in the travel of a substrate 205 on a swapper 230 is detected. For example, the controller 190 may stop the swapper 230 if the second LCF sensors 290 and third LCF sensors 295 detect that a substrate 205 deviates from the trajectory 246 by a threshold value, such as a deviation of 1 mm. The swapper 230 may be serviced and/or repaired such that future substrates 205 are swapped along the desired trajectory 246.

The second LCF sensors 290 and third LCF sensors 295 may be optical sensors used to detect the edges of the substrate 205 as it moves along the trajectory 246.

In some embodiments, the swapper assembly 120 is also a pre-heater such that the temperature of the substrates 205 is increased prior to the substrate being placed into the processing chamber 110. The substrate 205 may be pre-heated by radiative heating, convection, or conduction. One or more heat sources 280 may be disposed within the swapper chamber 223 above each swapper 230 that are used to increase the temperature of the substrates 205. The heat sources 280 discussed herein include radiant heat sources such as lamps, for example halogen lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein. In some embodiments, the substrate 205 may be heated by injecting a heated inert gas into the swapper assembly 120. In some embodiments, the arms 241, 242 of each swapper may include embedded heating elements to selectively heat a substrate 205 disposed on one of the arms 241, 242.

In some embodiments, the swapper assembly 120 may also be configured to cool, in addition to pre-heating, the substrates. The cooling can be accomplished by radiative cooling, convection, or conduction. For example, a cooled inert gas may be injected into the swapper assembly 120 to cool one substrate on one arm of the swapper 230 while the other arm of the swapper 230 is being pre-heated. For example, each arm 241, 242 of the swapper 230 may have one or more cooling channels formed therein such that a cooling fluid may be circulated through one of the arms 241, 242 to cool the substrate 205 disposed thereon.

The motor assembly 260 may be operated to move the substrates 205 through the swapper chamber 223 over a period of time sufficient to heat the substrates 205 to a desired temperature. For example, the motor assembly 260 may be used to pause (e.g., stop) the movement of the swappers 230 while the substrates 205 are positioned in the swapper chamber 223 underneath the heat sources 280 for a period of time.

In some embodiments, the motor assembly 260 includes a second belt. The shaft 262 includes a second pulley and the central gear 251 is coupled to a pulley. The second belt extends from the second pulley of the shaft 262 to the pulley coupled to the central gear 251 to rotate the central gear 251 relative to the body 231.

In some embodiments, the cluster tool includes five or more pairs of load locks 170 and processing chambers 110, and one swapper assembly 120 with a swapper 230 located between each pair of load locks 170 and processing chambers 110. The same motor assembly 260 may be used to operate each swapper 230, such as five or more swappers 230. For example, the swapper assembly 120 may have six swappers 230 driven by the same motor assembly 260.

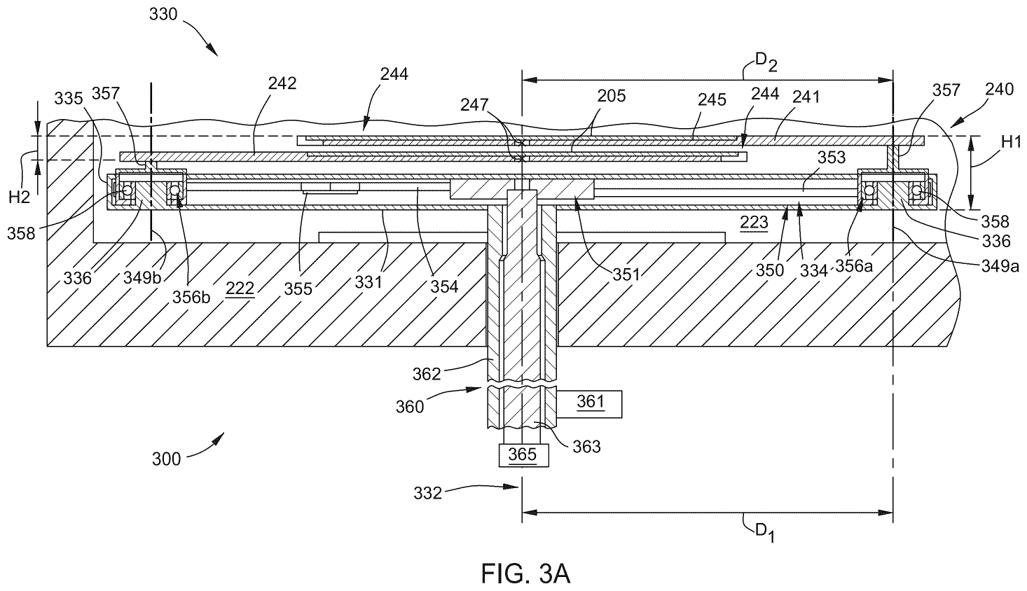

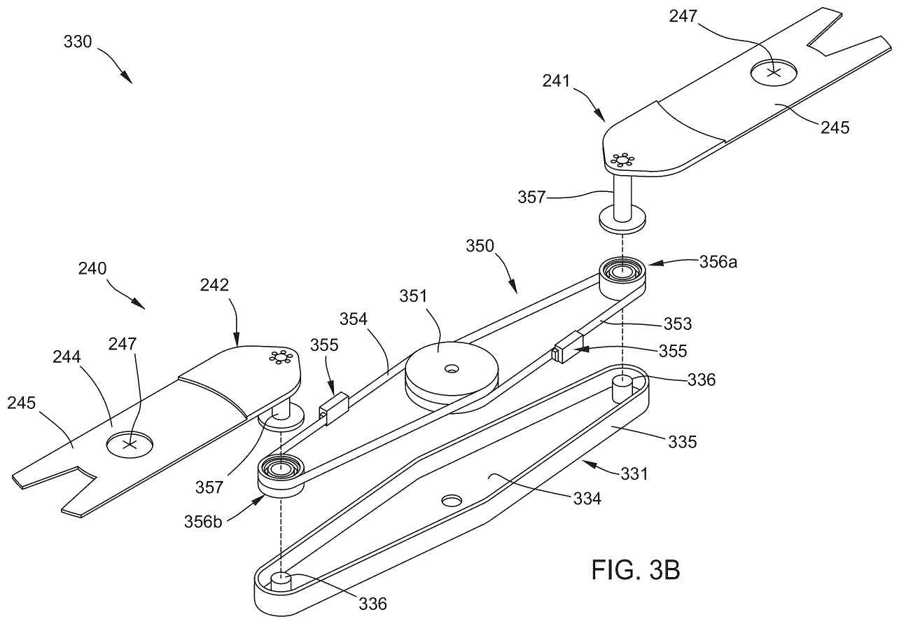

While FIGS. 2A-2C illustrate a swapper 230 with a gear assembly 250, the swapper 230 may be of another suitable design. For example, the swapper 230 may include one or more band or pulley systems used to actuate the arms 241, 242 to swap the substrates 205. FIGS. 3A-3B illustrate an exemplary embodiment of a pulley-type swapper.

Additionally, while the trajectory 246 shown in FIG. 2A is substantially linear, the swapper 230 can be used to move the substrate 205 along any suitable trajectory, including trajectories that are partially non-linear. For example, the trajectory may be made up of a plurality of trajectory segments, with some segments being at an angle to others, including some segments being linear segments while other segments are an arcuate path. However, each swapper 230 can be operated simultaneously to swap substrates 205 between pairs of load locks 170 and processing chambers 110.

In some embodiments, there are two slit valves 214 rather than the four slit valves 214 shown in FIG. 2A. The two slit valves 214 are positioned to open and close the tunnel 213 to two process chambers 110. In some embodiments, there are two second slit valves 272 rather than the four second slit valves 272 shown in FIG. 2A. The two second slit valves are positioned to open and close the opening to two load locks 170. In some embodiments, a single slit valve 214 is used to open and close every tunnel 213 and a single second slit valve 272 is used to open and close the opening to every load lock 170. Similarly, a single first slit valve 271 may be used to open and close the opening of every load lock 170 to allow the robots 102a to enter and exit the load locks 170. The cluster tool 100 can also have any suitable combination or configuration of slit valves, such as having a single slit valve 214 spanning multiple tunnels 213 while four second slit vales 272 are used to open and close the opening of a separate load lock 170.

The pumping system 181, gas panel 182, and power supply 183 are shared by each processing chamber 110. Communication between a processing chamber 110 and the pumping system 181, gas panel 182, and/or power supply 183 may be stopped and started, such as by opening or closing a valve or opening or closing a switch. This selective communication between a resource (e.g., pumping system 181, gas panel 182, and power supply 183) allows the resource to be conserved when one or more of the processing chambers 110 does not need the resource. Additionally, the selective communication also allows the resource to be used by one or more processing chambers 110 while one or more other processing chambers 110 are not using the resource.

FIG. 3A illustrates an embodiment of a swapper assembly 300 that may be substituted for the swapper assemblies 120 of any of the cluster tools 100. FIGS. 3A and 3B illustrate an exemplary pulley-type swapper 330 that may be substituted for the gear-type swapper 230 shown in the preceding figures.

FIG. 3A illustrates a schematic partial cross-sectional view of the swapper assembly 300 with the swapper 330 disposed therein. The swapper assembly 300 has similar components as the swapper assembly 120 as indicated by the reference signs without reciting the description of these components of the swapper assembly 120 for brevity. The swapper 330 has similar components as the swapper 230 as indicated by the reference signs without reciting the description of these components of the swapper 330 for brevity. Each swapper 330 is operable to swap substrates along the trajectory 246 between the load lock 170 and the processing chamber 110.

Each swapper 330 includes a base 331 (e.g., body), an arm assembly 240, and a pulley system 350. The base 331 includes an interior chamber 334 partially defined by walls 335 of the base 331. The pulley system 350 is at least partially disposed within the interior chamber 334 of the base 331. The pulley system 350 is operable to move the arms 241, 242. The arm assembly 240 is supported by the base 331. The base 331 may be connected to a first shaft 362 of a motor assembly 360. A motor 361 of the motor assembly 360 rotates the first shaft 362 about a central axis 332 of the swapper 330, thereby rotating the base 331 about the central axis 332. In some embodiments, one or more seals may be disposed around the first shaft 362 to seal the swapper chamber 223 from the outside environment while facilitating the rotation of the base 331 relative to the housing 222.

FIG. 3B illustrates a partial exploded view of the swapper 330 to show the interconnection of the exemplary pulley system 350 with other select components of the swapper 330. The exemplary pulley system 350 shown in FIG. 3B includes a central pulley 351, a first belt 353, a second belt 354, a first elbow pulley 356a, and a second elbow pulley 356b. The first arm 241 is attached to the first elbow pulley 356a and the second arm 242 is attached to the second elbow pulley 356b. In some embodiments, the central pulley 351 is in a fixed position (e.g., stationary). For example, the central pulley 351 may be fixed on a second shaft 363 (FIG. 3A) that extends into the interior chamber 334 through an opening in the walls 335 of the base 331 and through an opening of the first shaft 362. The motor assembly 360 (FIG. 3A) may include one or more bearing elements to facilitate the rotation of the base 331 and the first shaft 362 relative to the second shaft 363.

The central pulley 351 is shown as a multi-level pulley, in that the central pulley 351 accommodates both the first belt 353 and the second belt 354. Each level of the central pulley 351 may include a groove to engage the respective belt 353, 354. The elbow pulleys 356a,b are shown as single-level pulleys to guide a respective belt 353, 354. As shown, the second belt 354 is positioned above the first belt 353. The first belt 353 is wrapped around the first level of the central pulley 351 and the first elbow pulley 356a while second belt 354 is wrapped around the second level of the central pulley 351 and the second elbow pulley 356b.

In some embodiments, the first belt 353 and second belt 354 may each be at a desired tension during operation of the swapper 330 to facilitate the movement of the arms 241, 242. In some embodiments, the first belt 353 and second belt 354 each have an in-line tensioner 355 to maintain the tension of the belt. The in-line tensioner 355 is fixed to both ends of the corresponding belt 353, 354. The in-line tensioner 355 may be adjusted to apply a desired tension the corresponding belt 353, 354. In some embodiments, the corresponding belt 353, 354 may be stretched to a desired tension and then each end of the corresponding belt 353, 354 is fastened to the tensioner to hold the belt in tension.

The pulley system 350 may alternative have four bands instead of two belts wrapped around the central pulley 351 and a respective elbow pulley 356a,b. A first end of each band is anchored to the respective elbow pulley 356a,b and the second end of each band is anchored to the central pulley. For example, a first band may be anchored at one end to the first level of the central pulley 351 and the other end is anchored to a first level of the first elbow pulley 356a. A second band may be anchored to the second level of the central pulley 351 at one end and the other end of the second band is anchored to a second level of the first elbow pulley 356a. A third and fourth band may be anchored to the second elbow pulley 356b and the central pulley 351 in a similar manner. Each band may have an in-line tensioner 355.

Each arm 241, 242 has a shaft 357. The shaft 357 of the first arm 241 is attached to the first elbow pulley 356a and the shaft 357 of the second arm 342 is attached to the second elbow pulley 356b. For example, the shaft 357 of each arm may be attached to an outer race of the respective elbow pulley 356a,b. The first elbow pulley 356a, and thus the first arm 241, rotates about a first elbow axis 349a. The second elbow pulley 356b, and thus the second arm 242, rotates about a second elbow axis 349b.

Each of the elbow pulleys 356a,b may include bearing elements 358 (FIG. 3A) to facilitate the rotation of the shaft 357, and thus the respective arm 241, 242, relative to the base 331. For example, an inner race of each elbow pulley 356a,b may be mounted on a mounting shaft 336 of the base 331. An outer race is engaged with the respective belt 353, 354. The bearing elements 358 allow an outer race of each pulley 356a,b to rotate relative to the inner race.

FIG. 3A shows the motor assembly 360 connected with one swapper 330. The motor assembly 360 extends through the lower wall of the housing 222. The motor assembly 360 includes a motor 361 that rotates first shaft 362. The motor assembly 360 may include seals between components to prevent in inflow of gases into the swapper chamber 223 through the motor assembly 360.

In some embodiments, as the base 331 rotates, the elbow pulleys 356a,b rotate (e.g., orbit) around the central pulley 351 which does not rotate. The first belt 353 causes the first elbow pulley 356a to rotate as the base 331 rotates relative to the central pulley 351, thereby rotating the first arm 241 about the first elbow axis 349a. Similarly, the second belt 354 causes the second elbow pulley 356b to rotate as the base 331 moves relative to the central pulley 351, thereby rotating the second arm 242 about the second elbow axis 349b.

In some embodiments, the motor assembly 360 includes a second motor 365 configured to rotate the second shaft 363 about the central axis 332 to rotate the central pulley 351. Thus, the central pulley 351 may be rotatable relative to the base 331 by the second motor 365 to cause the first and second elbow pulleys 356a,b, and thus the arms 241, 242 attached thereto, to rotate about the elbow axis 349a,b. The first motor 361 is selectively operated to rotate the base 331 about the central axis 332. The second motor 365 is selectively operated to rotate the central pulley 351 to rotate the arms 241, 242 relative to the base 331. The movement of the base 331 and arms 241, 242 are coordinated to move each arm 241, 242 along the desired trajectory 246.

In some embodiments, the ratio of the central pulley 351 to each elbow pulley 356a,b is configured to achieve a desired shape and resolution of the trajectory 246 (e.g., linear movement) in which the substrate 205 is transferred between the load lock 170 and processing chamber 110. In some embodiments, the central pulley 351 has a diameter twice the diameter of the elbow pulleys 346a,b (e.g., 2:1 ratio) to achieve the linear trajectory 246.

In some embodiments, the elbow pulleys 356a,b may have a non-circular profile, such as a cam profile to move the arm 241, 242 along the desired trajectory between the load lock 170 and processing chamber 110. For example, the desired trajectory 246 may be a trajectory that includes at least one linear segment and at least one non-linear segment. The non-linear segment may be an arcuate segment. The non-liner profile is configured to facilitate the movement of the center point 247 along the linear and non-linear segments of the trajectory 246.

As shown in FIG. 3A, a distance D1 extends from the central axis 332 to each elbow axis 349a,b. In other words, each elbow pulley 346a,b is positioned on the base 331 at the same distance (shown as D1) from the central axis 332. The distance between the center point 247 and respective elbow axis 349a,b of the first and second arm 241, 242 is shown as D2. In some embodiments, this distance D2 is the same as distance D1. The distances D1 and D2 may be selected based on the desired reach (e.g., distance between the central axis 332 and the center point 247 when the arms 241, 242 are extended) of the swapper 330.

In some embodiments, the distance D1 and distance D2 may be unequal. For example, the first distance D1 may be less than the second distance D1. The second distance D2 may be selected based on the depth of the processing chamber 110 such that the arms 241, 242 can reach into the processing chamber 110 to place the substrate 205 above the substrate support 212.

In some embodiments, the substrate 205 may not be centered above the center point 247 of an arm 241, 242. In some embodiments, the distances D1 and D2 are selected to allow the swapper 330 to align the center of the substrate 205 within the processing chamber 110 and/or load lock 170.

In some embodiments, the swapper assembly 330 may include heat sources disposed in the swapper chamber 223, such as heat sources 280 described above and shown in FIG. 2B.

The first belt 353 and second belt 354 may precess (e.g., creep) around the central pulley 351 and the respective elbow pulleys 356a,b after repeated cycles of operation of the swapper 330. This belt precession can result in the arms 241, 242 deviating from the desired motion, such as causing a deviation in the trajectory 246. This belt precession can therefore interfere with aligning the center of the substrate 205 above the center of the processing chamber 110 and the load lock 170. The second LCF sensors 290 and third LCF sensors 295 may be used to monitor for a drift in the motion of the swapper 330 that indicates that the first belt 353 and second belt 354 have moved out of alignment with the central pulley 351 and the respective elbow pulley 356a,b. For example, the LCF sensors 290, 295 may detect that the center of the substrate 205 deviates from an expected position at one or more positions of the arms 241, 242, which indicates that the arms 241, 242 are deviating from the desired motion. The swapper 230 is then serviced to adjust the alignment of the belts 253, 254 to the desired alignment to correct the motion of the arms 241, 242.

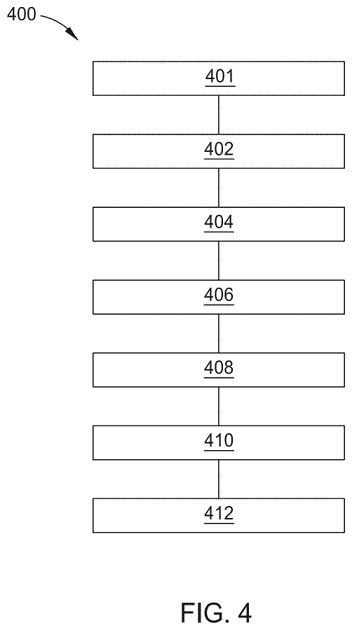

FIG. 4 illustrates a flow chart of an exemplary method 400 of operating a cluster tool, such as cluster tool 100. This method 400 can be occurring in multiple processing mainframes 101 of the cluster tool 100, such as cluster tool 100a, simultaneously.

At operation 401, a robot 102a of the factory interface 102 may place a substrate 205, such as a non-processed substrate, in the load lock transfer position in the load lock 170 through the open first slit valve 271 prior to the swapper 230 placing an arm, such as the second arm 242, into the load lock 170.

In some embodiments of operation 401, the robot 102a may be programmed and calibrated to repeatedly move the substrates 205 along an expected trajectory, such as expected trajectory 284 shown in FIG. 2C, to position the substrate 205 in the load lock transfer position within a respective load lock 170. Each robot 102a may be used to transfer a substrate 205 to one or more of the load locks 170, such as transferring a first substrate 205 to one load lock 170 and then transferring a second substrate 205 to a different load lock 170. The first LCF sensors 285 for each load lock 170 monitor the movement of the substrates 205 along the expected trajectory. The controller 190 uses the positional data obtained from the first LCF sensors 285 to determine if the substrate 205 is deviating from the expected trajectory as the substrate 205 is moved into the load lock 170. If a deviation is detected, then the controller 190 can generate an alert and/or stop the movement of the robot 102a. If a deviation is not detected, then the substrate 205 is assumed to be in the desired load lock transfer position within the load lock 170.

In some embodiments of operation 401, the controller 190 uses positional data obtained from the first LCF sensors 285 of a load lock 170 to maneuver the robot 102a to place the substrate 205 disposed thereon in the desired load lock transfer position. The robot 102a may be moved based on an iterative process, with the position of the robot 102a being adjusted based on the feedback from the first LCF sensors 285.

The substrate 205 is transferred from the robot 102a onto one or more support members, such as lift pins, within the load lock 170 once in the load lock transfer position. The robot 102a is then withdrawn from the load lock 170, allowing the first slit valve 271 to be closed. The load lock 170 is then least partially evacuated by the pumping system 181 while the first slit valve 271 and second slit valve 272 are closed to decrease the pressure within the load lock 170. For example, the pumping system 181 may be used to equalize pressure within the interior of the load lock 170 with the pressure within the swapper chamber 223.

At operation 402, at least two swappers 230, such as four swappers, are operated such that each swapper 230 has a first arm 241 disposed in an extended position within a processing chamber 110 and a second arm 242 disposed in an extended position within a load lock 170. The substrate 205 positioned within the load lock 170 is then transferred to the support 244 of the second arm 242. For example, the substrate 205 may be supported on lift pins within the load lock 170 that are lowered after the second arm 242 is placed in load lock 170 to transfer the substrate 205 onto the support 244 of the second arm 242. The lift 275 may be used to lower all the lift pins in each load lock 170 simultaneously. In some embodiments, where each load lock 170 has a different lift 275, each lift 275 is operated simultaneously to transfer each substrate 205 onto the support 244 of a respective second arm 242. The slit valves 214 are opened to accommodate the insertion of the first arm 242 into the processing chamber 110 and the slit valve 272 is opened to accommodate the movement of the second arm 242 into the load lock 170.

At operation 404, lift pins of a processing chamber 110 retract to lower a processed substrate 205 supported on the lift pins into engagement with the support surface 245 of the support 244 of each first arm 241. The lift pins are extended to lift the substrate 205 to a position above the substrate support 212 prior to operation 402 to allow each first arm 241 to move below the raised substrate 205. The lift pins in each processing chamber 110 may be moved simultaneously. For example, the lift pins in each processing chamber 110 may be operated simultaneously to transfer each substrate 205 to a respective each first arm 241 in unison. Operation 404 may occur before, after, or simultaneously with operation 402. Operation 404 may take more or less time to complete than operation 402. Operating the lift pins of each processing chamber 110 simultaneously with the lift pins of the load locks 170 reduces the overall time spent transferring the substrates 205 to the respective arms 241, 242 of each swapper 230. In other words, operating the lift pins of each processing chamber 110 and each load lock 170 simultaneously increases the throughput of the substrates through the cluster tool, such as through cluster tool 100.

At operation 406, the motor assembly 260 causes the at least two swappers 230 to swap the positions of the arms 241, 242, thereby moving the substrates 205 disposed thereon along the trajectory 246. Each second arm 242 is now located in the corresponding processing chamber 110 while each first arm 241 is located in the corresponding load lock 170. The unprocessed substrate 205 on each second arm 242 may be pre-heated as the position of the arms 241, 242 are swapped. The processed substrate 205 on the first arm 241 may be cooled as the position of the arms 241, 242 are swapped. The slit valves 214 and 272 are open while the arms 241, 242 swap positions.

The LCF sensors 290, 295 of the swapper assembly 120 associated with each swapper 230 monitor the movement of the unprocessed substrate 205 as it moves along the trajectory 246 from the load lock 170 to the processing chamber 110. The controller 190 analyzes the positional data obtained from the LCF sensors 290, 295 to determine if one or more of the unprocessed substrates 205 have deviated from the trajectory 246, which is indicative of the associated swapper 230 malfunctioning or is otherwise misaligned. If the controller 190 detects a deviation from the trajectory 246, then the controller 190 may generate an alert and/or cause one or more of the swappers 230 to stop moving. For example, the controller 190 may instruct the motor assembly 260 to stop moving all four swappers 230 if a deviation is detected.

At operation 408, each substrate 205 supported on the second arm 242 above the substrate support 212 within the processing chamber 110 is disengaged from the support 244 by extending the lift pins. The movement of the lift pins can accommodate the difference in heights of the supports 244 of the arms 241, 242. Each substrate 205 supported on the first arm 241 is removed therefrom by the support members, such as lift pins, within the load lock 170. The lift pins of each load lock 170 may be operated simultaneously such that each substrate 205 in each load lock 170 is disengaged from the support 244 of the second arm 242 in unison. Similarly, the lift pins of each processing chamber 110 may be operated simultaneously such that each substrate 205 in each processing chamber 110 is disengaged from the support 244 of the second arm 241 in unison. The lift pins in the load lock 170 and the lift pins in the processing chambers 110 may be moved simultaneously to increase the throughput of the cluster tool, such as cluster tool 100.

At operation 410, the motor assembly 260 is operated to move the arms 241, 242 of each swapper 230 to the retracted position. The lift pins in the processing chamber 110 are retracted, such the lift pins in each processing chamber 110 being retracted simultaneously, to engage the substrate 205 with the substrate support 212. The substrate 205 is then processed within the processing chamber 110. The slit valves 214, 271, 272, may be closed while the substrate 205 is processed. Additionally, the first slit valve 271 is opened, while the second slit valve 272 is closed, to allow a robot 102a of the factory interface 102 to retrieve the processed substrate 205 from the load lock 170. The robot 102a of the factory interface 102 then places the processed substrate 205 into a FOUP 103.

At operation 412, the motor assembly 260 is operated to continue to rotate each swapper 230 to position the second arm 242 back into the load lock 170 and to position the first arm 241 back into the processing chamber 110 after the substrate is processed while the substrate 205 is positioned above the substrate support 212 on lift pins. The method 400 may then repeat.

In some embodiments, the robot 102a has an end effector 202 with an over-under configuration. In other words, the robot 102a may have one surface configured to receive a processed substrate 205 from the load lock 170 while having another surface with an unprocessed substrate 205 disposed thereon to be placed into the load lock in the load lock transfer position.

While the foregoing is directed to embodiments of the present disclosure, other and further embodiments of the disclosure may be devised without departing from the basic scope thereof, and the scope thereof is determined by the claims that follow.

What is claimed is:

1. A cluster tool, comprising:
a factory interface including a first robot with an end effector;
a first processing mainframe coupled to the factory interface, including:
a first processing chamber;
a first load lock including a first opening facing the factory interface configured to receive the end effector of the first robot, the first load lock further including a first slit valve configured to selectively open and close the first opening;
at least one first LCF sensor disposed between the factory interface and the first slit valve; and
a swapper assembly disposed between the first load lock and the first processing chamber, wherein the swapper assembly includes a first swapper configured to swap substrates between the first processing chamber and the first load lock along a first trajectory.

2. The cluster tool of claim 1, further comprising:
a controller including a computer readable medium having instructions stored thereon for a method of placing a first substrate at a load lock transfer position within the first load lock with the first robot, the method comprising:
moving the first substrate disposed on the end effector of the first robot to the load lock transfer position along a second trajectory.

3. The cluster tool of claim 2, the method further comprising:
obtaining data from the at least one first LCF sensor as the first robot moves the first substrate into the first load lock;
determining if the first substrate deviates from the second trajectory based on the obtained data; and
stopping the first swapper or generating an alert when a deviation from the second trajectory is determined.

4. The cluster tool of claim 1, further comprising:
a controller including a computer readable medium having instructions stored thereon for a method of placing a first substrate at a load lock transfer position within the first load lock with the first robot using the at least one first LCF sensor, the method comprising:
obtaining a position of the first substrate disposed on the end effector of the first robot with the at least one first LCF sensor; and
adjusting a position of the first robot based on the obtained position of the first substrate to place the first substrate at the load lock transfer position within the first load lock.

5. The cluster tool of claim 1, the swapper assembly further comprising a plurality of second LCF sensors configured to monitor for a deviation in the first trajectory as the swapper swaps substrates between the first load lock and the first processing chamber.

6. The cluster tool of claim 1, the swapper assembly further comprising:
a second load lock including a second opening facing the factory interface configured to receive the end effector of the first robot, the second load lock further including a second slit valve configured to selectively open and close the second opening;
at least one second LCF sensor disposed between the factory interface and the second slit valve;
a second processing chamber; and
the swapper assembly is further disposed between the second load lock and the second processing chamber and includes a second swapper configured to swap substrates between the second processing chamber and the second load lock along a second trajectory, wherein the first swapper and the second swapper are operated simultaneously.

7. The cluster tool of claim 1, wherein the first trajectory is a linear trajectory.

8. A method of operating a cluster tool, comprising:
engaging a first substrate with a first robot of a factory interface of the cluster tool;
moving the first substrate engaged with the first robot along a first trajectory to place the first substrate at a load lock transfer position within a first load lock of the cluster tool; and
detecting for a deviation from the first trajectory using a first LCF sensor disposed between the factory interface and a first slit valve of the first load lock.

9. The method of claim 8, further comprising:
generating an alert when the deviation is detected.

10. The method of claim 8, further comprising:
transferring the substrate from the first robot to the first load lock.

11. The method of claim 10, further comprising:
engaging a second substrate with the first robot;
moving the second substrate engaged with the first robot along a second trajectory to place the second substrate at a load lock transfer position within a second load lock of the cluster tool; and
detecting for a deviation from the second trajectory using a second LCF sensor disposed between the factory interface and a second slit valve of the second load lock.

12. The method of claim 11, further comprising:
transferring the first substrate to a first swapper from the first load lock;
transferring the second substrate to a second swapper from the second load lock; and
operating the first swapper and the second swapper simultaneously to move the first substrate into a first processing chamber of the cluster tool along a third trajectory and to move the second substrate into a second processing chamber of the cluster tool along a fourth trajectory.

13. The method of claim 12, further comprising:
monitoring for a deviation of the first substrate from the third trajectory using one or more third LCF sensors; and
monitoring for a deviation of the second substrate from the fourth trajectory using one or more third LCF sensors.

14. The method of claim 12, further comprising:
generating an alert when the deviation from the third trajectory or the deviation from the fourth trajectory is detected.

15. A method of operating a cluster tool, comprising:
engaging a first substrate with a first robot of a factory interface of the cluster tool;
obtaining first positional data of the first substrate engaged with the first robot using a first LCF sensor disposed between the factory interface and an opened first slit valve of a first load lock of the cluster tool; and
adjusting a position of the first robot based on the obtained first positional data to place the first substrate at a load lock transfer position within the first load lock.

16. The method of claim 15, further comprising:
transferring the substrate from the first robot to the first load lock.

17. The method of claim 16, further comprising:
engaging a second substrate with the first robot;
obtaining second positional data of the second substrate engaged with the first robot using a second LCF sensor disposed between the factory interface and an opened second slit valve of a second load lock of the cluster tool;
adjusting a position of the first robot based on the obtained second positional data to place the second substrate at a load lock transfer position within the second load lock.

18. The method of claim 17, further comprising:
operating a first swapper of the cluster tool and a second swapper of the cluster tool simultaneously to move the first substrate from the first load lock and into a first processing chamber of the cluster tool along a third trajectory and to move the second substrate from the second load lock and into a second processing chamber of the cluster tool along a fourth trajectory.

19. The method of claim 18, further comprising:
monitoring for a deviation of the first substrate from the third trajectory using one or more third LCF sensors; and
monitoring for a deviation of the second substrate from the fourth trajectory using one or more fourth LCF sensors.

20. The method of claim 19, further comprising:
generating an alert when the deviation from the third trajectory or the deviation from the fourth trajectory is detected.
